(19) United States
(12) Patent Application Publication
(10) Pub. No.: US 2017/0089985 A1
(43) Pub. Date: Mar. 30, 2017

(54) METHOD FOR ESTIMATING AN ELECTRICAL CAPACITANCE OF A SECONDARY BATTERY

(71) Applicant: Robert Bosch GmbH, Stuttgart (DE)

(72) Inventors: Triantafyllos Zafiridis, Heilbronn (DE); Andre Boehm, Marbach am Neckar (DE); Michael Rueger, Muenchen (DE); Olivier Cois, Kernen (DE); Anne Heubner, Stuttgart (DE)

(21) Appl. No.: 15/315,790

(22) PCT Filed: May 18, 2015
(86) PCT No.: PCT/EP2015/060868

§ 371 Date: Dec. 2, 2016

(30) Foreign Application Priority Data
Jun. 4, 2014 (DE) 10 2014 210 603.6

(51) Int. Cl. G01R 31/36; B60L 11/18

(52) U.S. Cl. CPC G01R 31/3679; G01R 31/3651; B60L 11/1851

(57) ABSTRACT

The invention relates to a method for estimating an electrical capacitance of a battery, in particular, of an electrically drivable vehicle, comprising the steps: detecting of battery-specific state data; determining of a first value for the electrical capacitance by using an estimation algorithm and the battery-specific state data or by a measurement of the electrical capacitance; determining of a second value for the electrical capacitance by using an empirical aging model of the battery and the battery-specific state data; determining of a first weighted value for the electrical capacitance by multiplying the first value for the electrical capacitance by a first weighting factor; determining of a second weighted value for the electrical capacitance by multiplying the second value for the electrical capacitance by a second weighting factor; determining of a value sum by adding the weighted values for the electrical capacitance; determining of a weighting sum by adding the weighting factors; and determining of an estimation value for the electrical capacitance by dividing the value sum by the weighting sum.

### BACKGROUND OF THE INVENTION

Secondary batteries which, owing to their principle, are subject to aging are used in electrically drivable motor vehicles, in particular electric vehicles, hybrid electric vehicles and plug-in hybrid electric vehicles. In this case, the electrical capacity of a secondary battery tends to decrease with the age of said battery. This results in electrical energy which can be provided by a secondary battery, and therefore a range of an electrically drivable motor vehicle equipped with a secondary battery, falling over time.

It is known practice to use algorithms to estimate the capacity. On the one hand, there are estimation algorithms which use electrical properties of a secondary battery to infer or estimate the electrical capacity of the secondary battery. Such estimation algorithms generally have errors since, on the one hand, measuring electronics with limited accuracy are used to record input parameters to be taken into account by an estimation algorithm and, on the other hand, no corresponding dedicated measurements of the electrical capacity are possible or desirable in electrically drivable motor vehicles, but rather driving cycles which occur have to be analyzed. The driving cycles depend greatly on the respective driver and traffic conditions and, under certain circumstances, may be unsuitable for estimating the capacity.

If dedicated capacity measurements are nevertheless carried out, this is generally carried out at great intervals of time, with the result that errors occur between the capacity measurements owing to advancing aging of a secondary battery.

There are also empirical models for estimating the aging of secondary batteries, so-called empirical aging models which likewise have errors. In particular, it is difficult to infer actual aging of the secondary battery in an electrically drivable motor vehicle from aging of a secondary battery which was previously determined in the laboratory and is used as a basis for an empirical aging model.

Owing to their principle, learning algorithms for estimating capacities have a lag with respect to the actual aging of a secondary battery, in particular if the capacity estimations are carried out at great intervals of time, for example because workshop measurements are required and/or only particularly suitable driving cycles which possibly do not occur for a relatively long time are analyzed. In the extreme case, such particularly suitable driving cycles could never occur for analysis if the behavior of the respective driver is unsuitable for this. In such cases, the estimated electrical capacity lags behind the actual electrical capacity of a secondary battery, as is schematically illustrated in FIG. 1, as a result of which the remaining range of an electrically drivable motor vehicle is overestimated. Such an overestimation of the remaining range of an electrically drivable motor vehicle is generally accepted less than an underestimation of the remaining range since a breakdown of the motor vehicle is always intended to be avoided.

Furthermore, the algorithms used to measure the capacity have errors. Such errors may result both in an overestimation and in an underestimation of the range of a motor vehicle. In this case too, an overestimation of this range is less acceptable than an underestimation of the range.

If the interval of time between two capacity estimations is long, errors additionally occur which are greater than the actual errors of an estimation algorithm and increase, the longer the time until the next capacity estimation.

US 2013/0085696 A1 discloses a method for obtaining a deterioration in a battery, comprising the steps of
collecting data from the battery and data relating to the deterioration in the battery,
processing the collected data in order to obtain parameters relating to the deterioration in the battery,
creating and updating a deterioration model for the battery using the parameters which have been obtained, and
calculating the deterioration in the battery using the model and the parameters.

US 2010/0036626 A1 discloses an apparatus which estimates an aging state (“state of health”; SOH) of a battery on the basis of a battery voltage variation pattern. A data memory unit acquires and stores data relating to the battery voltage, the current and the temperature of sensors during each SOH estimation. A first state of charge (SOC) estimation unit estimates a first SOC by means of integration using the instantaneous data. A second SOC estimation unit estimates the open-circuit voltage from a voltage variation pattern and calculates and stores the second SOC, which is assigned to the open-circuit voltage and the temperature, taking into account correlations between the open-circuit voltage/temperature and the SOC. A convergence calculation unit calculates and stores a convergence value for a weighted mean value of the ratio of the second SOC variation to the first SOC variation. An SOH estimation unit estimates the capacity according to the weighted mean convergence value by means of correlation between the weighted mean convergence value and the capacity, estimates a relative ratio of the estimated capacity to the initial capacity, and stores it as an SOH.

### SUMMARY OF THE INVENTION

The invention relates to a method for estimating an electrical capacity of a battery, in particular of an electrically drivable motor vehicle, having the steps of:
acquiring battery-specific state data;
determining a first value for the electrical capacity using an estimation algorithm and the battery-specific state data or by measuring the electrical capacity;
determining a second value for the electrical capacity using an empirical aging model of the secondary battery and the battery-specific state data;
determining a first weighted value for the electrical capacity by multiplying the first value for the electrical capacity by a first weighting factor;
determining a second weighted value for the electrical capacity by multiplying the second value for the electrical capacity by a second weighting factor;
determining a value sum by adding the weighted values for the electrical capacity;
determining a weighting sum by adding the weighting factors; and
determining an estimated value for the electrical capacity by dividing the value sum by the weighting sum.

The invention is based on a superordinate algorithm which, in contrast to conventional algorithms, decisively reduces a probability of the electrical capacity of a secondary battery being overestimated in favor of the electrical capacity of the secondary battery being underestimated. As a result, a remaining range of an electrically drivable motor vehicle equipped with an aged secondary battery is estimated as being too low, rather than too high, thus again significantly reducing a probability of the motor vehicle breaking down. These advantages are achieved by taking into account, according to the invention, two values determined in different ways for the electrical capacity of the secondary battery.

A complementary filter can be used for this purpose. The empirical aging model may have any desired complexity and quality and depends greatly on a depth of aging tests of the battery cells of a secondary battery. The weighting factors can be kept constant between estimations of the electrical capacity of a secondary battery.

The invention does not restrict a range of an electrically drivable motor vehicle equipped with a secondary battery in any way at the start of a battery life since a particular capacity value does not need to be prophylactically subtracted at the start of the battery life in order to ensure that the electrical capacity of the secondary battery is not overestimated.

According to one alternative according to the invention, the electrical capacity of a secondary battery is measured in a dedicated manner, for example in a workshop, at particular intervals of time. The cycles between two such measurements may become accordingly longer, for example several months or years, that is to say the measurements or estimations become accordingly rarer. Between the measurements, both the empirical aging model and the estimation algorithm can be used with specially adapted weighting.

According to one advantageous configuration, battery-specific state data relating to a service life of the battery, given until the acquisition of the state data, or relating to at least the last operating cycle of a predefined length of time of the battery are acquired. The estimation algorithm can use the battery-specific state data, for example the last estimated electrical capacity, the electrical current or the current integral, the electrical voltage, voltage profiles, the ampere hour throughput, the temperature, temperature profiles and the like to estimate the electrical capacity of a secondary battery or a change in the capacity. These input signals may relate to the last operating cycle or else to the entire previous service life of the secondary battery. In addition to the battery-specific state data which are determined during a drive, battery-specific state data for the rest breaks between the drives may possibly be determined or estimated in the empirical aging model. Such battery-specific state data are, for example, the duration of a rest break and an average temperature of a secondary battery in the meantime.

According to another advantageous configuration, a driving cycle and/or a rest cycle of the vehicle is/are used as the operating cycle. The method is particularly suitable for those algorithms which operate in a cycle-based manner and provide, in each cycle, a result which consists of successful or unsuccessful estimation of the electrical capacity of a secondary battery or a change in the capacity with a certain quality if driving and rest times are evaluated in a cumulated manner. Use is preferably made of algorithms which use complete driving cycles to analyze the electrical capacity of a secondary battery or a change in the capacity.

According to another advantageous configuration, the estimation algorithm is used to generate a signal which describes a quality and/or an error of a last estimation of the electrical capacity.

Another advantageous configuration provides for the first value for the electrical capacity to be given a stronger weighting than the second value for the electrical capacity, the smaller the error in the last estimation of the electrical capacity, and for the second value for the electrical capacity to be given a stronger weighting than the first value for the electrical capacity, the greater the error in the last estimation of the electrical capacity. If the error in the last estimation is small, the first value determined for the electrical capacity or for the change in the capacity of the secondary battery can be given a stronger weighting (up to 100%) than the second value for the electrical capacity or the change in the capacity, determined from the empirical aging model of the secondary battery. A cross-fading function, for example a linear cross-fading function, can be used to implement this configuration.

According to another advantageous configuration, the first value for the electrical capacity is completely rejected if the error in the last estimation of the electrical capacity is greater than or equal to a predefined maximum error limit value. If the first value for the electrical capacity is accordingly completely rejected, only the second value for the electrical capacity or for the change in the capacity, determined from the empirical aging model of the secondary battery, can be used for the next estimation of the electrical capacity.

According to another advantageous configuration, a greatest possible change in the electrical capacity is determined using the empirical aging model and the battery-specific state data. As a result, the method for estimating an electrical capacity can be used between operations of determining estimated values for the electrical capacity of the battery. If a focus of an improvement to be achieved is on the fact that, for example, the remaining range of an electrically drivable motor vehicle or the remaining capacity of a secondary battery of an electrically drivable motor vehicle is never intended to be overestimated, a worst-case aging data supply of the empirical aging model can be selected, in which the greatest possible change in the electrical capacity is used. If, in contrast, the focus is on the most accurate possible estimation of the electrical capacity of a secondary battery at all times, optimized data supply of the empirical aging model can be selected, which describes the expected aging of the secondary battery as precisely as possible. This minimizes the error in the entire estimation.

According to another advantageous configuration, the estimated value for the electrical capacity is used to correct the empirical aging model. This makes it possible to further improve the quality of the estimation of the electrical capacity of a secondary battery.

### BRIEF DESCRIPTION OF THE DRAWINGS

The invention is explained by way of example below with reference to the attached figures on the basis of preferred exemplary embodiments, in which case the features described below may constitute an aspect of the invention both taken per se in each case and in a different combination with one another. In the drawings

FIG. 1: shows a schematic illustration of an estimation of the electrical capacity of a secondary battery according to a conventional method,

FIG. 2: shows a schematic illustration of an estimation of the electrical capacity of a secondary battery according to one exemplary embodiment of a method according to the invention, and

FIG. 3: shows a block diagram of an exemplary sequence of a method according to the invention.

### DETAILED DESCRIPTION

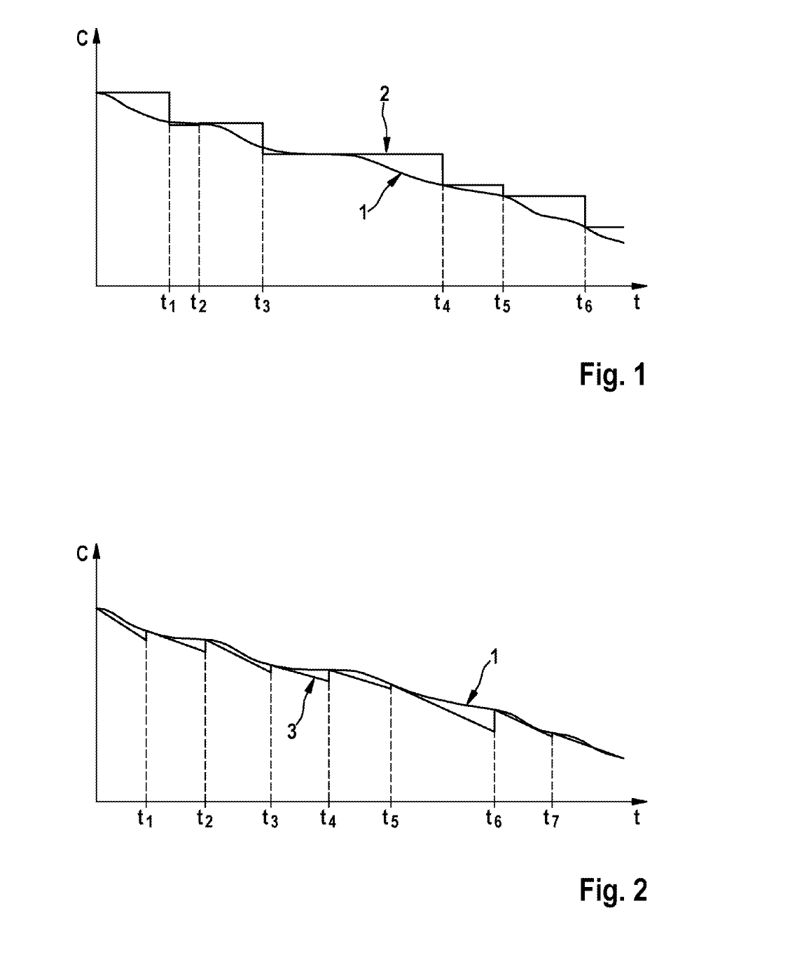

FIG. 1 shows a schematic illustration of an estimation of the electrical capacity of a secondary battery according to a conventional method. FIG. 1 illustrates both a curve 1 for the real electrical capacity of a secondary battery and a stepped curve 2 for an electrical capacity of the secondary battery estimated using an estimation algorithm. The electrical capacity of the secondary battery is respectively estimated at the times t₁ to t₆ using the estimation algorithm. The respectively estimated electrical capacity is retained until the next estimation. The actual electrical capacity of the secondary battery falls between the estimations of the electrical capacity by means of the estimation algorithm, as a result of which an error in one estimation increases until the next estimation.

FIG. 2 shows a schematic illustration of an estimation of the electrical capacity of a secondary battery according to one exemplary embodiment of a method according to the invention. FIG. 2 illustrates both a curve 1 for the real electrical capacity of a secondary battery and a curve 3 for an electrical capacity of the secondary battery estimated using the method according to the invention. The electrical capacity of the secondary battery is respectively estimated at the times t₁ to t₇ using the method according to the invention. The electrical capacity of the secondary battery falls between the estimations of the electrical capacity according to the data in the empirical aging model used. In the exemplary embodiment shown in FIG. 2, the focus of an improvement to be achieved is on the fact that the remaining range of an electrically drivable motor vehicle or the remaining capacity of the secondary battery of the electrically drivable motor vehicle is never intended to be overestimated. A worst-case aging data supply of the empirical aging model is selected for this purpose. That is to say, the greatest possible change in the capacity which can occur under the respectively given circumstances is determined from the empirical aging model.

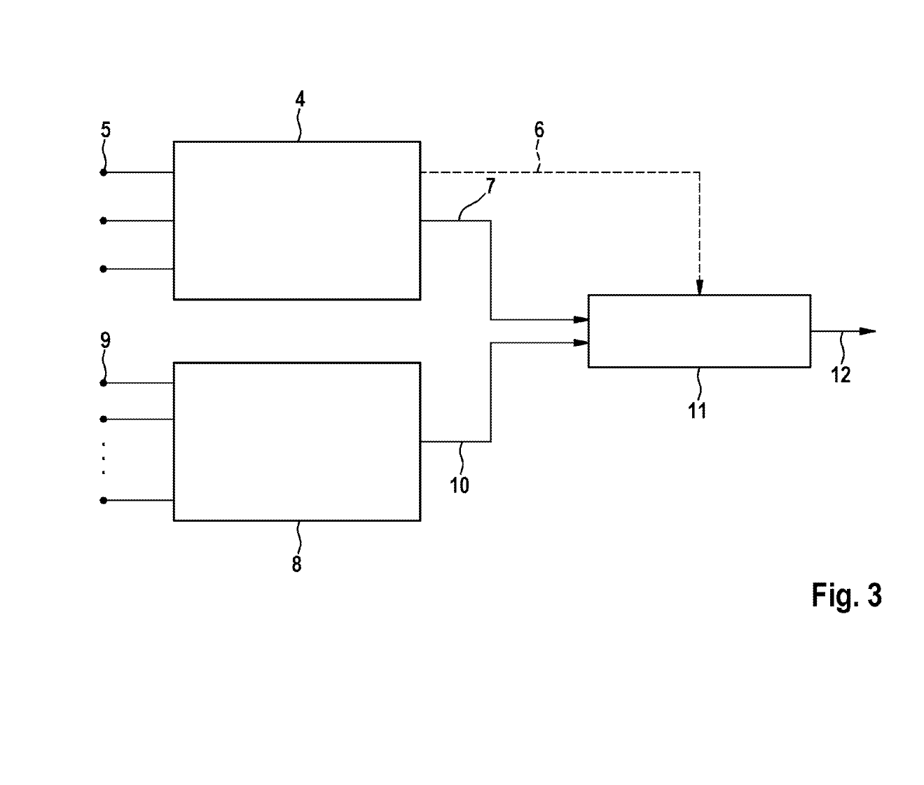

FIG. 3 shows a block diagram of an exemplary sequence of a method according to the invention.

The estimation algorithm 4 is symbolically illustrated, to the left of which there are a plurality of signal inputs 5 and to the right of which there are two signal outputs 6 and 7. The last estimated electrical capacity of the secondary battery is supplied to the estimation algorithm 4 via a signal input 5. Battery-specific state data, for example the electrical current, the electrical voltage, the temperature or the like, can be supplied to the estimation algorithm 4 via the further signal inputs 5. A signal describing a quality and/or an error of a last estimation of the electrical capacity can be tapped off at the signal output 6. A first value for the electrical capacity, determined using the estimation algorithm 4 and the battery-specific state data, can be tapped off at the signal output 7.

The empirical aging model 8 is also symbolically illustrated, to the left of which there are a plurality of signal inputs 9 and to the right of which there is a signal output 10. The last estimated electrical capacity of the secondary battery is supplied to the empirical aging model 8 via a signal input 9. Battery-specific state data, for example the ampere hour throughput, the temperature or the like, can be supplied to the empirical aging model 8 via the further signal inputs 9. A second value for the electrical capacity, determined using the empirical aging model 8 and the battery-specific state data, can be tapped off at the signal output 10.

The signals or values for the electrical capacity which can be tapped off at the signal outputs 6, 7 and 10 are processed in a method step 11, in which case a first weighted value for the electrical capacity is determined by multiplying the first value for the electrical capacity by a first weighting factor, a second weighted value for the electrical capacity is determined by multiplying the second value for the electrical capacity by a second weighting factor, a value sum is determined by adding the weighted values for the electrical capacity, a weighting sum is determined by adding the weighting factors, and an estimated value for the electrical capacity is determined by dividing the value sum by the weighting sum. This estimated value is present at the signal output 12.

1. A method for estimating an electrical capacity of a battery, having the steps of:
acquiring battery-specific state data;
determining a first value for the electrical capacity using an estimation algorithm (4) and the battery-specific state data or by measuring the electrical capacity;
determining a second value for the electrical capacity using an empirical aging model (8) of the battery and the battery-specific state data;
determining a first weighted value for the electrical capacity by multiplying the first value for the electrical capacity by a first weighting factor;
determining a second weighted value for the electrical capacity by multiplying the second value for the electrical capacity by a second weighting factor;
determining a value sum by adding the weighted values for the electrical capacity;
determining a weighting sum by adding the weighting factors; and
determining an estimated value for the electrical capacity by dividing the value sum by the weighting sum.

2. The method as claimed in claim 1, characterized in that battery-specific state data relating to a service life of the battery, given until the acquisition of the state data, or relating to at least the last operating cycle of a predefined length of time of the battery are acquired.

3. The method as claimed in claim 2, characterized in that a driving cycle and a rest cycle of the vehicle is/are used as the operating cycle.

4. The method as claimed in claim 1, characterized in that the estimation algorithm (4) is used to generate a signal which describes a quality and/or an error of a last estimation of the electrical capacity.

5. The method as claimed in claim 4, characterized in that the first value for the electrical capacity is given a stronger weighting than the second value for the electrical capacity, the smaller the error in the last estimation of the electrical capacity, and in that the second value for the electrical capacity is given a stronger weighting than the first value for the electrical capacity, the greater the error in the last estimation of the electrical capacity.

6. The method as claimed in claim 4, characterized in that the first value for the electrical capacity is completely rejected if the error in the last estimation of the electrical capacity is greater than or equal to a predefined maximum error limit value.

7. The method as claimed in claim 1, characterized in that a greatest possible change in the electrical capacity is determined using the empirical aging model (8) and the battery-specific state data.

8. The method as claimed in claim 1, characterized in that the estimated value for the electrical capacity is used to correct the empirical aging model (8).

9. The method as claimed in claim 1, wherein the battery is a battery of an electrically drivable vehicle.

10. The method as claimed in claim 2, characterized in that a driving cycle is used as the operating cycle.

11. The method as claimed in claim 2, characterized in that a rest cycle of the vehicle is used as the operating cycle.
